(19) United States
(12) Patent Application Publication
(10) Pub. No.: US 2015/0072165 A1
(43) Pub. Date: Mar. 12, 2015

(54) BONDING MEMBER

(71) Applicant: MURATA MANUFACTURING CO., LTD., Nagaokakyo-Shi (JP)

(72) Inventors: Tomohiro Sunaga, Nagaokakyo-shi (JP); Daisuke Megumi, Nagaokakyo-shi (JP); Yoshihiko Takano, Nagaokakyo-shi (JP); Hidekiyo Takaoka, Nagaokakyo-shi (JP)

(21) Appl. No.: 14/547,262

(22) Filed: Nov. 19, 2014

Related U.S. Application Data
(63) Continuation of application No. PCT/JP2013/065972, filed on Jun. 10, 2013.

(30) Foreign Application Priority Data
Jun. 19, 2012 (JP) 2012-138076

(51) Int. Cl. H05K 3/40; B23K 35/26; B23K 35/02; C25D 3/56; C25D 5/16

(52) U.S. Cl. CPC H05K 3/40; C25D 3/56; C25D 5/16; B23K 35/0238; B23K 35/262; H05K 2203/04
USPC 428/610; 205/95

(57) ABSTRACT

A bonding member that includes a plating film containing a Cu—Ni alloy as its main constituent. In this plating film, the Cu mass ratio Cu/(Cu+Ni) is increased and decreased between 0.7 and 0.97 in the film thickness direction. In addition, the amplitude between the increase and decrease in the Cu mass ratio is larger than 0.1. Therefore, when the plating film containing the Cu—Ni alloy as its main constituent and Sn-based solder material or the like are joined by soldering, an intermetallic compound layer with a high melting point is formed. In addition, the plating film has a layer with a slow reaction rate, and thus can slow the reaction rate of alloying reaction between the Cu—Ni alloy and a Sn-based metal.

### CROSS REFERENCE TO RELATED APPLICATIONS

The present application is a continuation of International application No. PCT/JP2013/065972, filed Jun. 10, 2013, which claims priority to Japanese Patent Application No. 2012-138076, filed Jun. 19, 2012, the entire contents of each of which are incorporated herein by reference.

### FIELD OF THE INVENTION

The present invention relates to a bonding member, for example, for bonding between an attachment electrode and an electronic component which are formed on a wiring substrate.

### BACKGROUND OF THE INVENTION

The wiring substrate described in Patent Document 1 has a pad for external connection, which includes a surface plating layer. The surface plating layer is formed from a combination of Ni and Au, a combination of Ni, Pd, and Au, or a combination of Sn or Sn with Ag. In addition, the pad for external connection is formed from Cu or a Cu alloy.

Patent Document 1: Japanese Patent Application Laid-Open No. 2008-300507

### SUMMARY OF THE INVENTION

Now, in the case of mounting an electronic component onto the wiring substrate, the electronic component is connected to the wiring substrate via the pad for external connection. In this case, typically solder is used. However, the melting point of the solder after connecting the pad for external connection and the electronic component does not change very much from before the connection, and there is a problem, for example, that when the solder is passed through a reflow furnace again for mounting additional electronic component, the solder is re-melted to shift the bonded position of the electronic component connected once.

Therefore, an object of the present invention is to provide a bonding member which has excellent solder joint characteristics, and suppresses problems such as bonded positions shifted after reflow, and in particular, even after another reflow.

The bonding member according to the present invention is a bonding member including a plating film containing a Cu—Ni alloy as its main constituent, which is characterized in that the Cu mass ratio Cu/(Cu+Ni) is increased and decreased between 0.7 and 0.97 in the film thickness direction of the plating film, and the amplitude between the increase and decrease in Cu mass ratio is larger than 0.1.

The bonding member according to the present invention has a Cu—Ni alloy plating film as a main constituent of the bonding member, the Cu mass ratio Cu/(Cu+Ni) is increased and decreased between 0.7 and 0.97 in the film thickness direction of the plating film, and the amplitude between the increase and decrease in Cu mass ratio is larger than 0.1. When the Cu—Ni alloy plating film containing a Cu—Ni alloy as its main constituent for the bonding member according to the present invention and a Sn-based solder material or the like are joined with a soldering, an intermetallic compound (Intermetallic Compounds: IMC) layer with a high melting point is formed at the joint part. This intermetallic compound layer has a high melting point, the low-melting-point component such as the Sn-based metal is unlikely to remain after the soldering, and a joint with high joint reliability is thus achieved which gives excellent strength in high temperature and gives conductivity. In addition, because of having the layer which is slow in the reaction rate of the alloying reaction between the Cu—Ni alloy and the Sn-based metal, the reaction rate of the alloying reaction between the Cu—Ni alloy and the Sn-based metal can be made slower, and thus, in particular, the self-alignment property after reflow can be improved.

In addition, in the joining by soldering, an oxide film remover may be used in some cases. Gas is generated when an organic component of the oxide film remover is decomposed and volatilized during the reflow, and when the alloying reaction rate is high between the Cu—Ni alloy and the Sn-based metal, the gas may fail to be vented, and remain as voids, thereby leading to defective bonding in some cases. When the Cu—Ni alloy plating film for the bonding member according to the present invention is joined by soldering with the use of a Sn-based solder material, the time for gas venting can be secured by slowing the alloying reaction between the Cu—Ni alloy and the Sn-based metal, and the gas can be thus avoided from remaining as voids in the joint part.

According to the present invention, a bonding member can be achieved which has excellent solder joint characteristics, and suppresses problems such as shifted bonding positions after reflow, and in particular, even after another reflow.

The above-mentioned object, other objects, features, and advantageous effects of this invention will be further evident from the following description of MODE FOR CARRYING OUT THE INVENTION with reference to the drawings.

### BRIEF EXPLANATION OF THE DRAWINGS

FIG. 1 is a schematic composition diagram illustrating an embodiment of a bonding member according to the present invention.

FIG. 2 is a diagram showing the respective content rates of Cu and Ni in the film thickness direction of a Cu—Ni alloy plating film.

FIG. 3 is a diagram showing the relationship between the content rate of Ni in a Cu—Ni alloy and the reaction rate.

FIG. 4 is a diagram showing a temperature profile for reflow in an experimental example.

FIG. 5 is a diagram showing the respective content rates of Cu and Ni in the film thickness direction of a Cu—Ni alloy plating film according to Example 1.

FIG. 6 is a diagram showing the respective content rates of Cu and Ni in the film thickness direction of a Cu—Ni alloy plating film according to Comparative Example 1.

FIG. 7 is a diagram showing the respective content rates of Cu and Ni in the film thickness direction of a Cu—Ni alloy plating film according to Comparative Example 2.

### DETAILED DESCRIPTION OF THE INVENTION

(Structure of Cu—Ni Plating Film for Bonding Member)

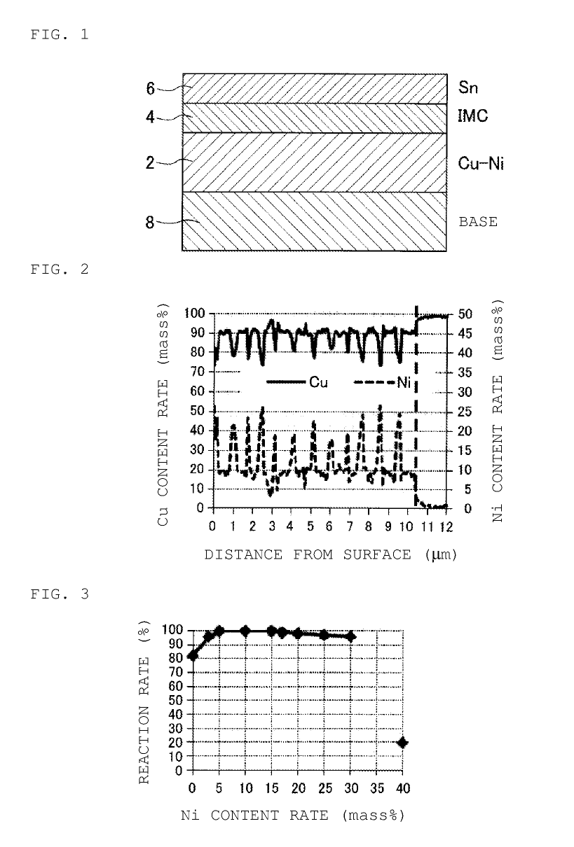

FIG. 1 is a schematic composition diagram illustrating an embodiment of a Cu—Ni plating film for a bonding member according to the present invention, which is formed on the surface of a base such as an attachment electrode of a wiring substrate with electronic components, etc. mounted thereon. A Cu—Ni alloy plating film 2 is formed on the surface of a base 8 formed on the surface of a wiring substrate (not shown), and formed as a Cu—Ni alloy plating film. Furthermore, FIG. 1 shows a Sn-based solder layer 6 formed from a Sn-based solder material on the surface of the Cu—Ni alloy plating film 2, and an intermetallic compound layer 4 produced between the Cu—Ni alloy plating film 2 and the Sn-based solder layer 6.

The Cu—Ni alloy plating film 2 contains a Cu—Ni alloy as its main constituent. The Cu mass ratio Cu/(Cu+Ni) in the Cu—Ni alloy plating film 2 is 0.7 to 0.97 (70 mass % to 97 mass %). Furthermore, this Cu mass ratio is increased and decreased between 0.7 and 0.97 in the film thickness direction of the Cu—Ni alloy plating film 2. The amplitude between the increase and decrease in Cu mass ratio is larger than 0.1 (10 mass %). More specifically, the difference in Cu mass ratio between the maximum content rate and the minimum content rate is larger than 0.1 (10 mass %).

FIG. 2 shows increases and decreases of the Cu and Ni content rates in the film thickness direction of the Cu—Ni alloy plating film 2 for the bonding member. It is to be noted that there is, but not limited thereto, a number of cycles of increases and decreases of Cu and Ni in the film thickness direction of the Cu—Ni alloy plating film 2 for the bonding member in FIG. 2. This Cu—Ni alloy plating film 2 can be formed on the surface of the base 8 by various types of means. For example, the Cu—Ni alloy plating film 2 may be formed on the surface of the base 8 by varying the current density during electrolytic plating, varying the concentrations of Cu ions and Ni ions in a plating bath during plating, or changing the stirring intensity during plating.

The intermetallic compound layer 4 is placed between the Cu—Ni alloy plating film 2 and the Sn-based solder layer 6. The intermetallic compound layer 4 is an alloy layer containing Cu, Ni, and Sn as its main constituents. This intermetallic compound layer 4 is formed at the boundary between the Cu—Ni alloy plating film 2 and the Sn-based solder layer 6 in a step of bonding electronic components, etc. with the Sn-based solder layer 6 as will be described later.

The Sn-based solder layer 6 is placed on the surface of the intermetallic compound layer 4. The Sn-based solder layer 6 contains Sn as its main constituent. The Sn-based solder layer 6 is formed from a Sn-based solder material.

In the Cu—Ni alloy plating film 2, when the Cu mass ratio Cu/(Cu+Ni) falls within the range of 0.85 to 0.95, the reaction of alloying is efficiently developed between the Cu—Ni alloy and the Sn-based metal. More specifically, when the mass ratio falls within this range, problems such as deterioration in self-alignment property may be caused in some cases, because of the excessive high rate of the alloying between the Cu—Ni alloy and the Sn-based solder material. However, the Cu—Ni alloy plating film 2 for the bonding member according to the present invention has a Cu mass ratio Cu/(Cu+Ni) between 0.7 to 0.97, and has an increase and a decrease in the Cu mass ratio, and furthermore, the amplitude of the increase and decrease in Cu mass ratio is larger than 0.1. Thus, because the reaction rate of the alloying between the Cu—Ni alloy and the Sn-based solder material can be slowed, a bonding member can be achieved which can improve the self-alignment property of, for example, an electronic component mounted on a wiring substrate, during reflow.

In addition, in the joining, an oxide film remover may be used in some cases. Gas is generated when an organic component of the oxide film remover is decomposed and volatilized during the reflow, and when the reaction rate of the alloying is high between the Cu—Ni alloy and the Sn-based solder material, the gas may fail to be vented, and remain as voids, thereby leading to defective bonding in some cases. However, the bonding member according to the present invention can, because of having the composition mentioned above, slow the reaction rate of the alloying between the Cu—Ni alloy and the Sn-based solder material to avoid the gas from remaining as voids in the joint part. In particular, the formation for increasing the cycle numbers of the increase and decrease in Cu and Ni in the film thickness direction of the Cu—Ni alloy plating film 2 can uniformly slow the reaction rate of the alloying between the Cu—Ni alloy and the Sn-based solder material between respective zones in the film thickness direction, and thus further avoid voids from remaining.

(Method for Producing Cu—Ni Plating Film for Bonding Member)

Next, an embodiment will be described in regard to a method for producing the Cu—Ni alloy plating film 2 for the thus configured bonding member.

First, a Cu—Ni alloy plating film for a bonding member is formed as the Cu—Ni alloy plating film 2 for the bonding member, on the surface of the base 8 formed on the surface of a wiring substrate with electronic components, etc., mounted thereon. For example, this Cu—Ni alloy plating film 2 is plated in such a way that the Cu mass ratio Cu/(Cu+Ni) is adjusted to 0.7 to 0.97 (70 mass % to 97 mass %) by varying the current density during electrolytic plating, and the Cu mass ratio is increased and decreased in the film thickness direction of the Cu—Ni alloy plating film 2.

More specifically, in order for the Cu mass ratio to be increased and decreased in the film thickness direction of the Cu—Ni alloy plating film 2, during electrolytic plating, electrolytic plating at a predetermined current density for a predetermined period of time, and then, electrolytic plating at a current density that is higher or lower than the predetermined current density, which are regarded as one cycle, are carried out. It is to be noted that at least one cycle or more is implemented as this cycle number. As a result, the Cu—Ni alloy plating film 2 is formed to have an amplitude between the increase and decrease in the Cu mass ratio of larger than 0.1 (10 mass %). It is to be noted that as the method for forming the Cu—Ni alloy plating film 2 containing a Cu—Ni alloy as its main constituent, the concentrations of Cu ions and Ni ions in a plating bath may be varied during plating, or the stirring intensity during plating may be changed for the formation.

Next, the Sn-based solder layer 6 containing Sn as its main constituent, for example, is formed in joining electronic components, etc., onto the surface of the Cu—Ni alloy plating film 2 by soldering with the use of a Sn-based solder material. During this joining by soldering, the intermetallic compound layer 4 is formed at the boundary between the Cu—Ni alloy plating film 2 and the Sn-based solder layer 6. More specifically, the intermetallic compound layer 4 and the Sn-based solder layer 6 are formed around the same time (in the same step).

Typically, in the case of obtaining the solder joint by placing a Sn-based solder material on the surface of the Cu—Ni alloy plating film 2 with a Cu mass ratio Cu/(Cu+Ni) of 0.7 to 0.97, the first metal (Cu—Ni alloy) and the second metal (Sn) have favorable diffusivity in a step such as reflow, and the intermetallic compound layer 4 containing Cu, Ni, and Sn, as its main constituents is thickly formed at a low temperature and in a short period of time. This intermetallic compound layer 4 has a high melting point, thus providing a joint with excellent strength in high temperature.

In particular, in the composition which efficiently develops the reaction of alloying between the Cu—Ni alloy and the Sn-based solder material (Sn-based metal), the Cu mass ratio in the Cu—Ni alloy falls within the range of 0.85 to 0.95. Accordingly, as departing from this composition, the reaction rate of the alloying is decreased.

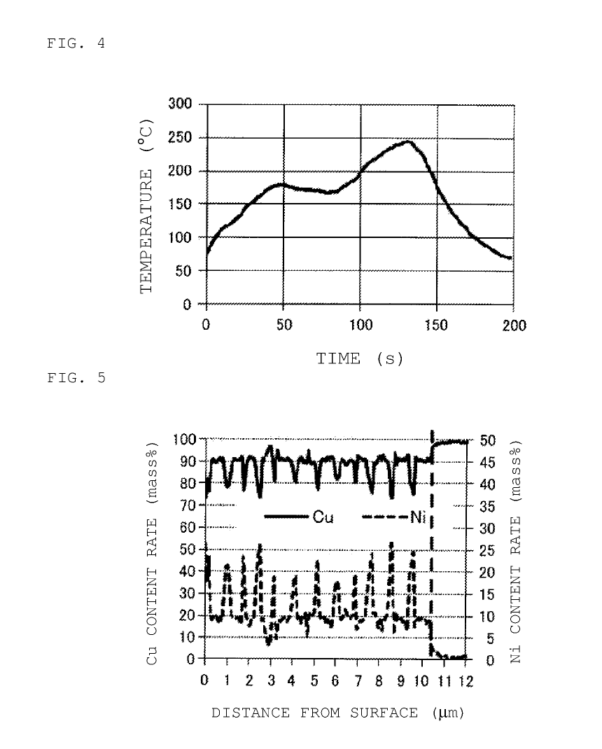

FIG. 3 herein shows the relationship between the content rate of Ni in the Cu—Ni alloy and the reaction rate. It is to be noted that the reaction rate is determined as follows. More specifically, a Cu—Ni alloy pellet (φ 10 mm, 5 mm in thickness) of predetermined composition, and another Cu—Ni alloy pellet with a solder pellet (Sn-3Ag-0.5Cu, the same size as the Cu—Ni alloy pellet) placed on the surface of the alloy pellet is subjected to heat treatment for 10 minutes at 250° C., and then to a DSC analysis to quantify unreacted Sn from the amount of endothermic heat for melting the unreacted Sn, and calculate the reaction rate. Therefore, the reaction rate refers to the proportion of solder changed to the intermetallic compound layer 4.

From FIG. 3, when the Cu content is 0.7 to 0.97 (the Ni content is 0.03 to 0.3), this reaction rate of the alloying is adequately fast within a range for practical use. Further, as will be described later, when the compositional ratio between Cu and Ni is increased and decreased in the film thickness direction of the Cu—Ni alloy plating film 2 in this range, the self-alignment property of, for example, electronic components mounted on a wiring substrate is improved during reflow.

In this case, the intermetallic compound layer 4 containing Cu, Ni, and Sn as its main constituents can grow thick in a shorter period of time than a conventional intermetallic compound layer composed of Cu and Sn. The mechanism for allowing the intermetallic compound layer 4 containing Cu, Ni, and Sn as its main constituents to grow thick in a shorter period of time is assumed as follows.

When the bonding member contains a Cu—Ni alloy as its main constituent, and when the Cu mass ratio Cu/(Cu+Ni) falls within the range of 0.7 to 0.97, the intermetallic compound layer 4 is formed between the Sn-based solder layer 6 and the Cu—Ni alloy plating film 2 as described previously, by the formation of the Cu—Ni alloy plating film 2 for the bonding member, and the formation of the Sn-based solder layer 6 through the solder joint on the surface of the Cu—Ni alloy plating film 2. More specifically, the alloying reaction proceeds from the interface between the Cu—Ni alloy and the Sn-based metal placed on the surface of the alloy.

However, due to the large difference in lattice constant between the Cu—Ni alloy as a main constituent of the Cu—Ni alloy plating film 2 to serve as a base for the Sn-based solder layer 6 and the intermetallic compound layer 4 formed by reaction with Sn, the intermetallic compound layer 4 is partially peeled from the Cu—Ni alloy plating film 2. As a result, the surface of the Cu—Ni alloy plating film 2 is partially exposed to bring the Cu and Ni of the exposed Cu—Ni alloy plating film 2 into contact with Sn in the Sn-based solder material.

Accordingly, again, the intermetallic compound layer 4 is progressively formed which contains Cu, Ni, and Sn as its main constituents. This process is repeated to make the reaction between the Cu and Ni of the Cu—Ni alloy plating film 2 and Sn in the Sn-based solder material proceed at a high speed, thereby providing the thick intermetallic compound layer 4.

Furthermore, as described above, the reason that the self-alignment property is improved is assumed to be as follows. The reaction surface disappears when the reaction proceeds from the interface between the Cu—Ni alloy and Sn toward the base side to completely exhaust either the Cu—Ni alloy or Sn through the reaction. When the composition of the Cu—Ni alloy plating film 2 has a Cu content of 0.85 to 0.95 with a uniform Cu mass ratio in the film thickness direction of the Cu—Ni alloy plating film 2, the alloying reaction may proceed excessively fast, thereby resulting in failure of self-alignment in some cases. However, as long as there is a layer of composition with a Cu content departing from the range of 0.85 to 0.95 (provided that the Cu mass ratio falls within the range of 0.7 to 0.97), that is, a layer with a slow reaction rate, in the form of a layer in the Cu—Ni alloy plating film 2, the overall reaction rate can be slowed for producing the intermetallic compound layer 4, and the self-alignment property of, for example, electronic components mounted on a wiring substrate is thus considered to be improved during reflow.

More specifically, when the Cu—Ni alloy plating film 2 for the bonding member according to the present invention is formed on, for example, an attachment electrode of a wiring substrate, and then the wiring substrate is passed through a reflow furnace so as to bond an electronic component with the Cu—Ni alloy plating film 2 interposed therebetween with the use of a Sn-based solder material, the time for self alignment can be secured because of the long reaction time for alloying between the Cu—Ni alloy plating film 2 and the Sn-based solder material.

### Experimental Example

In the experimental example, as the following Example 1, Example 2, Comparative Example 1, Comparative Example 2, Comparative Example 3, and Comparative Example 4, six types of samples including Cu—Ni alloy plating films formed under different conditions were created by applying Cu—Ni alloy electrolytic plating to the surface of a base to form a Cu—Ni alloy plating film containing a Cu—Ni alloy as its main constituent, and then applying Sn electrolytic plating to form a Sn plating layer, and the samples were evaluated.

A glass epoxy substrate (wiring substrate) with a number of Cu electrode patterns formed on the surface of the substrate was used for the base. More specifically, with the Cu electrode patterns on the glass epoxy substrate as the base, the surfaces of the Cu electrode patterns were subjected to electrolytic plating. The Cu electrode patterns each have a rectangle shape of 0.8 mm in the X direction (transverse direction) and 1.5 mm in the Y direction (longitudinal direction). Furthermore, two of the Cu electrode patterns at an interval of 0.8 mm in the X direction (transverse direction) are regarded as a pair of Cu electrodes, and ten pairs of the Cu electrodes are arranged each at intervals of 1.9 mm in the X direction and ten pairs at intervals of 2.9 mm in the Y direction. The Cu electrode patterns were prepared for 200 pieces. That is, 100 pairs of the Cu electrodes were prepared.

### Example 1

In the Cu—Ni alloy electrolytic plating for the sample according to Example 1, as a plating solution, a mixed aqueous solution of 0.03 mol/L of nickel sulfate hexahydrate, 0.06 mol/L of copper sulfate pentahydrate, and 0.15 mol/L of sodium gluconate was used into which an appropriate amount of a film conditioner was put. The pH of the plating solution was 4.5, and the temperature of the plating solution was 40° C. Then, the electrolytic plating current set at 80 A/m² for 2 minutes and set at 150 A/m² for 5 minutes was regarded as one cycle, and 12 cycles were implemented. As a result, a Cu—Ni alloy plating film of 10 μm in thickness, containing a Cu—Ni alloy as its main constituent was formed on the surface of the base (Cu electrode pattern).

### Example 2

In the Cu—Ni alloy electrolytic plating for the sample according to Example 2, as a plating solution, a mixed aqueous solution of 0.03 mol/L of nickel sulfate hexahydrate and 0.2 mol/L of copper sulfate pentahydrate was used into which appropriate amounts of a complexing agent and a film conditioner were put. The pH of the plating solution was 5.0, and the temperature of the plating solution was 50° C. Then, the electrolytic plating current set at 80 A/m² for 1 minute and set at 300 A/m² for 2 minutes was regarded as one cycle, and 12 cycles were implemented. As a result, a Cu—Ni alloy plating film of 10 μm in thickness, containing a Cu—Ni alloy as its main constituent was formed on the surface of the base (Cu electrode pattern).

### Comparative Example 1

In the Cu—Ni alloy electrolytic plating for the sample according to Comparative Example 1, as a plating solution, a mixed aqueous solution of 0.03 mol/L of nickel sulfate hexahydrate, 0.06 mol/L of copper sulfate pentahydrate, and 0.15 mol/L of sodium gluconate was used into which an appropriate amount of a film conditioner was put. The pH of the plating solution was 4.5, and the temperature of the plating solution was 40° C. Then, the electrolytic plating current was set at 150 A/m² to carry out the Cu—Ni alloy electrolytic plating for 110 minutes. As a result, a Cu—Ni alloy plating film of 10 μm in thickness, containing a Cu—Ni alloy as its main constituent was formed on the surface of the base (Cu electrode pattern).

### Comparative Example 2

In the Cu—Ni alloy electrolytic plating for the sample according to Comparative Example 2, as a plating solution, a mixed aqueous solution of 0.03 mol/L of nickel sulfate hexahydrate, 0.06 mol/L of copper sulfate pentahydrate, and 0.15 mol/L of sodium gluconate was used into which an appropriate amount of a film conditioner was put. The pH of the plating solution was 4.5, and the temperature of the plating solution was 40° C. Then, the electrolytic plating current was set at 80 A/m² to carry out the Cu—Ni alloy electrolytic plating for 130 minutes. As a result, a Cu—Ni alloy plating film of 10 μm in thickness, containing a Cu—Ni alloy as its main constituent was formed on the surface of the base (Cu electrode pattern).

### Comparative Example 3

In the Cu—Ni alloy electrolytic plating for the sample according to Comparative Example 3, as a plating solution, a mixed aqueous solution of 0.03 mol/L of nickel sulfate hexahydrate and 0.2 mol/L of copper sulfate pentahydrate was used into which appropriate amounts of a complexing agent and a film conditioner were put. The pH of the plating solution was 5.0, and the temperature of the plating solution was 50° C. Then, the electrolytic plating current was set at 300 A/m² to carry out the Cu—Ni alloy electrolytic plating for 20 minutes. As a result, a Cu—Ni alloy plating film of 10 μm in thickness, containing a Cu—Ni alloy as its main constituent was formed on the surface of the base (Cu electrode pattern).

### Comparative Example 4

In the Cu—Ni alloy electrolytic plating for the sample according to Comparative Example 4, as a plating solution, a mixed aqueous solution of 0.03 mol/L of nickel sulfate hexahydrate and 0.2 mol/L of copper sulfate pentahydrate was used into which appropriate amounts of a complexing agent and a film conditioner were put. The pH of the plating solution was 5.0, and the temperature of the plating solution was 50° C. Then, the electrolytic plating current was set at 80 A/m² to carry out the Cu—Ni alloy electrolytic plating for 70 minutes. As a result, a Cu—Ni alloy plating film of 10 μm in thickness, containing a Cu—Ni alloy as its main constituent was formed on the surface of the base (Cu electrode pattern).

Sn electrolytic plating was common to the respective samples according to Example 1, Example 2, Comparative Example 1, Comparative Example 2, Comparative Example 3, and Comparative Example 4, and Sn-232 (trade name) from DIPSOL CHEMICALS CO., LTD. was used as a plating solution. Then, the electrolytic plating current was set at 50 A/m² to carry out the Sn electrolytic plating for 6 minutes. Thereafter, three types of samples were dried for 15 minutes in an oven at 65° C. As a result, a Sn plating layer of approximately 1 μm in thickness was formed on the surface of the Cu—Ni alloy plating film for the respective samples according to Example 1, Comparative Example 1, and Comparative Example 2.

Further, in order to measure the Cu and Ni content rates in the film thickness direction of the Cu—Ni alloy plating film, after the Cu—Ni alloy electrolytic plating, 10 electrodes were randomly selected from the 200 electrodes of the substrates according to Example 1, Example 2, Comparative Example 1, Comparative Example 2, Comparative Example 3, and Comparative Example 4, masked with a masking tape for preventing the formation of Sn plating layers, and then subjected to Sn electrolytic plating to separately prepare samples for measuring the content rates of Cu and Ni.

Subsequently, a Sn oxide film remover (from TAMURA CORPORATION, Trade Name: BF-31) was applied by printing to a mounting section of the substrate with the Cu—Ni alloy plating film and Sn plating layer formed thereon, and 100 pieces of laminated ceramic capacitors of 2012 size (2.0 mm×1.2 mm×1.2 mm: see the JEITA standards, etc.) were placed onto the section per substrate with the use of an automatic chip mounting system, preheated for 70 seconds at 130° C. to 180° C., and mounted under a general reflow condition of 30 seconds at 220° C. or higher with a peak temperature of 245° C. FIG. 4 shows a temperature profile with respect to the time change for the reflow. It is to be noted that the electrode structure for the laminated ceramic capacitors has a Ni plating layer of 3 μm formed on the surface of a Cu external electrode, and further has a Sn plating layer of 3 μm formed on the surface of the Ni plating layer. In this way, 5 sheets of substrates were prepared for each condition, and 500 pieces of laminated ceramic capacitor chips were evaluated for the self-alignment property described later for each condition.

Evaluation

(1) Cu—Ni Distribution at Cross Section of Substrate

For the analysis of the Cu and Ni content rates in the film thickness direction of the Cu—Ni alloy plating film, in relation to the ten masked electrodes (the electrodes with no Sn plating formed) of the substrate plated under each condition, cross sections of electrode central sections were polished in the plating film thickness direction, and subjected to FIB (focused ion beam) processing treatment. In this way, cross sections were obtained from the Cu—Ni alloy plating films for the measurement. The Cu—Ni alloy plating film sections of the cross sections were subjected to mapping analysis (hereinafter, referred to as WDX mapping analysis) with a wavelength-dispersive X-ray spectrometer (WDX) to figure out the Cu and Ni content rates in the film thickness direction.

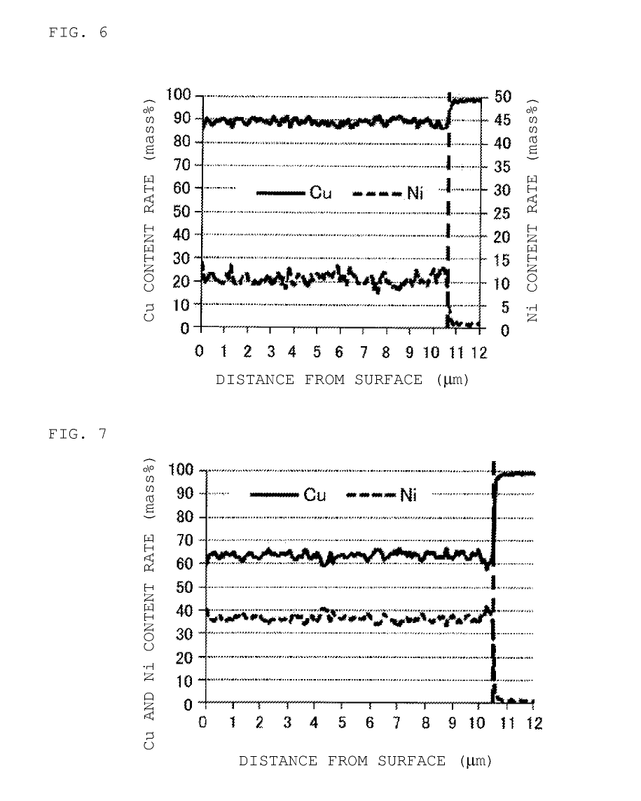

FIG. 5 shows the result of the WDX mapping analysis on the Cu—Ni alloy plating film according to Example 1, FIG. 6 shows the result of the WDX mapping analysis on the Cu—Ni alloy plating film according to Comparative Example 1, and FIG. 7 shows the result of the WDX mapping analysis on the Cu—Ni alloy plating film according to Comparative Example 2.

In the case of an increased current density during the Cu—Ni alloy electrolytic plating, through the use of the fact that Cu as a noble metal is likely to be incorporated, an adjustment was made so as to reach around the target composition. More specifically, in the case of 80 A/m², a Ni-rich layer would be formed with respect to the target composition. In Example 1 (varying current density), the Cu mass ratio Cu/(Cu+Ni) had a maximum value of 96.72 mass % and a minimum value of 73.58 mass %, and the amplitude between the increase and decrease in the Cu mass ratio was larger than 10 mass %. Further, Example 2, not shown, achieved results similar to those in Example 1. In Comparative Example 1 (constant current density), the Cu mass ratio Cu/(Cu+Ni) had a maximum value of 92.26 mass % and a minimum value of 86.02 mass %, and the amplitude between the increase and decrease in the Cu mass ratio was smaller than 10 mass %. Further, Comparative Example 3, not shown, achieved results similar to those in Comparative Example 1. In Comparative Example 2 (constant current density), the Cu mass ratio Cu/(Cu+Ni) had a maximum value of 66.54 mass % and a minimum value of 57.58 mass %, and the amplitude between the increase and decrease in the Cu mass ratio was smaller than 10 mass %. Further, Comparative Example 4, not shown, achieved results similar to those in Comparative Example 2. In addition, this tendency has been shown in the same way in each case, while ten electrodes were checked under each condition of Example 1, Example 2, Comparative Example 1, Comparative Example 2, Comparative Example 3, and Comparative Example 4.

(2) Quantitative Determination of Low Melting Point Metal Component in Intermetallic Compound Layer

After the reflow, laminated ceramic capacitors were mounted, and a solidified reaction product including the intermetallic compound layer 4 after the reflow was cut out for each of the substrates according to Example 1, Example 2, Comparative Example 1, Comparative Example 2, Comparative Example 3, and Comparative Example 4. The cut reaction product was subjected to differential scanning calorimetry (DSC measurement) under the conditions of measurement temperature: 30° C. to 300° C.; rate of temperature increase: 5° C./min; and reference: Al₂O₃ in a N₂ atmosphere.

From the amount of endothermic heat for the melting endothermic peak at the melting temperature of the low-melting-point metal component on the measured DSC chart, the amount of the remaining low-melting-point metal component was quantified to calculate the content rate (mass %) of the remaining low-melting-point metal. Then, the content rate of the remaining low-melting-point metal was evaluated as ⊙ (excellent) in the case of 0 to 3 mass %, as ∘ (good) in the case of more than 3 mass % up to 30 mass %, or as x (disapproval) in the case of more than 30 mass %. As a result, in Example 1, Example 2, Comparative Example 1, and Comparative Example 3, the content rates of the remaining low-melting-point metal were all regarded as ⊙ (excellent), and it has been thus appreciated that excellent bonding characteristics are achieved when the bonding members are used. On the other hand, in Comparative Example 2 and Comparative Example 4, the content rates of the remaining low-melting-point metal were regarded as x (disapproval), and it has been determined that there is a possibility that components will be shifted in the implementation of additional reflow in the case of use as the bonding member.

In addition, as a result of analyzing the cut reaction products by X-ray diffractometry, it has been appreciated that the intermetallic compound films formed in Example 1, Example 2, Comparative Example 1, and Comparative Example 3 were all composed of intermetallic compounds containing Sn, Cu, and Ni, as their main constituents.

(3) Self-Alignment Property

For each of the conditions according to Example 1, Example 2, Comparative Example 1, Comparative Example 2, Comparative Example 3, and Comparative Example 4, 5 sheets of the substrates, that is, 500 pieces of the chips were evaluated for self-alignment property. The chips 0.2 mm or more shifted in the X direction or Y direction, or the chips with the direction L of chip tilted at 5° or more to the X direction of the substrate after reflow were regarded as defectives.

TABLE 1

| | | | Comparative | Comparative | Comparative | Comparative |
|---|---|---|---|---|---|---|
| | Example 1 | Example 2 | Example 1 | Example 2 | Example 3 | Example 4 |
| Self- | 0/500: | 0/500: | 13/500: | 5/500: | 2/500: | 11/500: |
| Alignment | NG | NG | NG | NG | NG | NG |
| Property | | | | | | |

Laminated ceramic capacitors were mounted onto the substrates created by the respective plating methods according to Example 1, Example 2, Comparative Example 1, Comparative Example 2, Comparative Example 3, and Comparative Example 4, and checked for self-alignment property in the case of applying reflow. The results are shown in Table 1. Example 1 and Example 2 had self-alignment properties improved with the Cu content rate in the range of 73 to 97 mass %, and with an increase or a decrease of more than 10 mass % in composition. This is presumed to be because the control for moderately slowing the reaction rate buys time for self-alignment of laminated ceramic capacitors.

It is to be noted that this invention is not to be considered limited to the previously described embodiment, but variously modified within the spirit of the invention.

### DESCRIPTION OF REFERENCE SYMBOLS

2 Cu—Ni alloy plating film
4 Intermetallic compound layer
6 Sn-based solder layer
8 Base

1. A bonding member comprising:
a plating film containing a Cu—Ni alloy as a main constituent,
wherein a Cu mass ratio Cu/(Cu+Ni) of the plating film is increased and decreased between 0.7 and 0.97 in a film thickness direction of the plating film, and an amplitude between the increase and decrease in the Cu mass ratio is larger than 0.1.

2. The bonding member according to claim 1, further comprising a Sn-based solder layer adjacent the plating film.

3. The bonding member according to claim 2, further comprising an intermetallic compound layer between the plating film and the Sn-based solder layer.

4. The bonding member according to claim 3, wherein the intermetallic compound layer contains Cu, Ni and Sn as main constituents thereof.

5. The bonding member according to claim 3, wherein the Cu mass ratio is within a range of 0.85 to 0.95.

6. The bonding member according to claim 1, wherein the Cu mass ratio is within a range of 0.85 to 0.95.

7. A method of forming a bonding member, the method comprising:
forming a plating film containing a Cu—Ni alloy as a main constituent on a surface of a base such that a Cu mass ratio Cu/(Cu+Ni) of the plating film is increased and decreased between 0.7 and 0.97 in a film thickness direction of the plating film, and an amplitude between the increase and decrease in the Cu mass ratio is larger than 0.1.

8. The method of forming a bonding member according to claim 7, wherein the plating film is formed by varying a current density during electrolytic plating.

9. The method of forming a bonding member according to claim 7, wherein the plating film is formed by varying concentrations of Cu ions and Ni ions in a plating bath during plating.

10. The method of forming a bonding member according to claim 7, wherein the plating film is formed by changing a stirring intensity during plating.

11. The method of forming a bonding member according to claim 7, further comprising forming a Sn-based solder layer on a surface of the plating film.

12. The method of forming a bonding member according to claim 11, further comprising forming an intermetallic compound layer at a boundary between the plating film and the Sn-based solder layer.

13. The method of forming a bonding member according to claim 12, wherein the intermetallic compound layer contains Cu, Ni and Sn as main constituents thereof.

14. The method of forming a bonding member according to claim 12, wherein the Cu mass ratio is within a range of 0.85 to 0.95.

15. The method of forming a bonding member according to claim 7, wherein the Cu mass ratio is within a range of 0.85 to 0.95.
